(19) United States
(12) Patent Application Publication
(10) Pub. No.: US 2026/0013235 A1
(43) Pub. Date: Jan. 8, 2026

(54) ELECTROSTATIC DISCHARGE CIRCUIT, DISPLAY SUBSTRATE, AND DISPLAY DEVICE

(71) Applicants: Hefei Xinsheng Optoelectronics Technology Co., Ltd., Hefei, Anhui (CN); BOE Technology Group Co., Ltd., Beijing (CN); Beijing BOE Technology Development Co., Ltd., Beijing (CN)

(72) Inventors: Zhangtao WANG, Beijing (CN); Ran ZHANG, Beijing (CN); Zhixiang ZOU, Beijing (CN); Liang LIN, Beijing (CN); Yongxian XIE, Beijing (CN); Zhan WEI, Beijing (CN)

(21) Appl. No.: 18/881,784

(22) PCT Filed: May 30, 2024
(86) PCT No.: PCT/CN2024/096244

§ 371 Date: Jan. 7, 2025

(30) Foreign Application Priority Data
May 31, 2023 (CN) 202310646729.5

(51) Int. Cl. H10D 89/60; H10D 86/40

(52) U.S. Cl. CPC H10D 89/811; H10D 86/423; H10D 86/443

(57) ABSTRACT

Provided is an electrostatic discharge circuit. The electrostatic discharge circuit includes a first transistor, a second transistor, and a third transistor. A gate and a first electrode of the first transistor are coupled to a first node, the first node being coupled to a signal line, and a second electrode of the first transistor is coupled to a second node; a gate and a first electrode of the second transistor are both coupled to a third node, the third node being coupled to an electrostatic protection line, and a second electrode of the second transistor is coupled to a fourth node, the fourth node being coupled to the second node; a gate of the third transistor is coupled to the second node, a first electrode of the third transistor is coupled to the first node, and a second electrode of the third transistor is coupled to the third node.

The present disclosure is a U.S. national stage of international application No. PCT/CN2024/096244, filed on May 30, 2024, which claims priority to Chinese patent application No. 202310646729.5, filed on May 31, 2023, and entitled “ELECTROSTATIC DISCHARGE CIRCUIT, DISPLAY SUBSTRATE AND DISPLAY DEVICE”, the entire contents of which are incorporated herein by reference.

### TECHNICAL FIELD

The present disclosure relates to the field of display technology and more particularly to an electrostatic discharge circuit, a display substrate and a display device.

### BACKGROUND

In the display field, static electricity is one of the main causes of product failure.

### SUMMARY

Embodiments of the present disclosure provide an electrostatic discharge circuit, a display substrate and a display device.

According to some embodiments of the present disclosure, an electrostatic discharge circuit is provided. The electrostatic discharge circuit includes:

a first transistor, wherein a gate and a first electrode of the first transistor are both coupled to a first node, the first node is coupled to a signal line, and a second electrode of the first transistor is coupled to a second node:

a second transistor, wherein a gate and a first electrode of the second transistor are both coupled to a third node, the third node is coupled to an electrostatic protection line, and a second electrode of the second transistor is coupled to a fourth node: and

a third transistor, wherein a gate of the third transistor is coupled to the second node, a first electrode of the third transistor is coupled to the first node, and a second electrode of the third transistor is coupled to the third node.

In some embodiments, the electrostatic discharge circuit further includes:

N fourth transistors, wherein first electrodes and second electrodes of the N fourth transistors are sequentially coupled in series, a first electrode of a first fourth transistor is coupled to the second electrode of the third transistor, and a second electrode of an N-th fourth transistor is coupled to the third node: and

N fifth transistors, wherein first electrodes and second electrodes of the N fifth transistors are sequentially coupled in series, a first electrode of a first fifth transistor is coupled to the second node, and a second electrode of an N-th fifth transistor is coupled to the fourth node:

wherein in a direction from the first transistor to the second transistor, a gate of an i-th fourth transistor is coupled to a second electrode of an i-th fifth transistor, and a gate of the i-th fifth transistor is coupled to a first electrode of the i-th fourth transistor, wherein N is a positive integer greater than or equal to 1, and i is a positive integer not greater than N.

In some embodiments, N is 1 or 2.

In some embodiments, a width of a channel of the fourth transistor is equal to a width of a channel of the third transistor, and a length of the channel of the fourth transistor is equal to a length of the channel of the third transistor.

In some embodiments, a width-to-length ratio of the channel of the third transistor is less than a width-to-length ratio of a channel of the fifth transistor, and the length of the channel of the third transistor is greater than a length of the channel of the fifth transistor.

In some embodiments, the width-to-length ratio of the channel of the third transistor is (2-5) μm/(40-80) μm.

In some embodiments, a width-to-length ratio of a channel of the first transistor and a width-to-length ratio of a channel of the second transistor are both (2-5) μm/(5-10) μm.

In some embodiments, the width-to-length ratio of the channel of the fifth transistor is (2-5) μm/(5-10) μm.

In some embodiments, the electrostatic discharge circuit is disposed on a side of a base, and active layers of various transistors in the electrostatic discharge circuit are disposed in a same layer:

wherein an active layer of the third transistor and active layers of the N fourth transistors are sequentially arranged along a first straight line, and an active layer of the first transistor, active layers of the N fifth transistors, and an active layer of the second transistor are sequentially arranged along a second straight line, wherein the first straight line and the second straight line are spaced apart from each other.

In some embodiments, length directions of channels of the various transistors in the electrostatic discharge circuit are all a first direction, and the first straight line and the second straight line both extend along the first direction and are parallel to each other.

In some embodiments, mobilities of materials of active layers of various transistors are greater than or equal to 10.

In some embodiments, materials of active layers of various transistors include a metal-oxide semiconductor material.

In some embodiments, the active layers of the various transistors each include a first active sub-layer and a second active sub-layer which are stacked on the side of the base, and the first active sub-layer is closer to the base than the second active sub-layer is:

wherein a material of the first active sub-layer includes indium gallium zinc tin oxide, indium gallium oxide, or any combination thereof; and a material of the second active sub-layer includes indium gallium zinc oxide, and an atomic ratio of indium, gallium, and zinc in the material of the second active sub-layer is 1:1:1.

In some embodiments, a thickness of the first active sub-layer ranges from 10 nm to 20 nm, and a thickness of the second active sub-layer ranges from 10 nm to 50 nm.

In some embodiments, the electrostatic discharge circuit further includes:

an active material layer disposed on a side of a base, wherein the active material layer includes active layers of various transistors:

a first insulating layer disposed on a side of the active material layer that faces away from the base:

a first metal layer disposed on a side of the first insulating layer that faces away from the base, wherein the first metal layer includes gates of the various transistors:

a second insulating layer disposed on a side of the first metal layer that faces away from the base: and

a second metal layer disposed on a side of the second insulating layer that faces away from the base, wherein the second metal layer includes first electrodes and second electrodes of the various transistors, and the first electrode and the second electrode are coupled to a first conductorized region and a second conductorized region of a corresponding active layer, respectively.

In some embodiments, various transistors in the electrostatic discharge circuit are all N-type transistors.

According to some embodiments of the present disclosure, a display substrate is provided. The display substrate has a display region and a non-display region, and the display substrate includes the electrostatic discharge circuit as described in above embodiments. The electrostatic discharge circuit is disposed in the non-display region.

In some embodiments, the display substrate further includes: a signal line and a common electrode line: wherein a gate of a first transistor in the electrostatic discharge circuit is coupled to the signal line, and a gate of a second transistor in the electrostatic discharge circuit is coupled to the common electrode line.

According to some embodiments of the present disclosure, a display device is provided. The display device includes a signal line, an electrostatic protection line, and the electrostatic discharge circuit provided in any one of the embodiments of the present disclosure. Alternatively, the display device includes a power supply assembly, and the display substrate provided in any one of the embodiments of the present disclosure. The power supply assembly is configured to supply power to the display substrate.

The foregoing summary is merely intended to describe the present disclosure but not limit the present disclosure in any way. In addition to the schematic aspects, embodiments, and features described above, further aspects, embodiments, and features of the present disclosure will become readily understandable by reference to the accompanying drawings and the detailed description below:

### BRIEF DESCRIPTION OF DRAWINGS

In the accompanying drawings, unless otherwise specified, the same reference numeral throughout the multiple drawings indicates the same or similar parts or elements. These drawings are not necessarily drawn to scale. It should be understood that these drawings only depict some embodiments of the present disclosure and should not be construed as limiting the scope of the present disclosure.

FIG. 1 is a schematic diagram of an electrostatic discharge circuit:

FIG. 2 is a schematic diagram of a partial structure of the electrostatic discharge circuit shown in FIG. 1:

FIG. 3 is a schematic diagram of an electrostatic discharge circuit according to some embodiments of the present disclosure:

FIG. 4 is a schematic diagram of an electrostatic discharge circuit according to some embodiments of the present disclosure:

FIG. 5 is a schematic diagram of an electrostatic discharge circuit according to some embodiments of the present disclosure:

FIG. 6 is a schematic structural diagram of an active layer of a transistor according to some embodiments of the present disclosure:

FIG. 7 is a schematic structural diagram of a third transistor in an electrostatic discharge circuit according to some embodiments of the present disclosure;

FIG. 8 is a schematic diagram of a partial structure of the electrostatic discharge circuit shown in FIG. 4:

FIG. 9 is a schematic diagram showing a comparison of an I-V characteristic curve of an electrostatic discharge circuit where N=1 according to some embodiments of the present disclosure and an I-V characteristic curve of the electrostatic discharge circuit shown in FIG. 1:

FIG. 10 is a schematic diagram of a display substrate according to some embodiments of the present disclosure;

FIG. 11A is a sectional schematic diagram of a display substrate after an active layer is formed according to some embodiments of the present disclosure:

FIG. 11B is a sectional schematic diagram of a display substrate after a common electrode is formed according to some embodiments of the present disclosure:

FIG. 11C is a sectional schematic diagram of a display substrate after a pixel electrode is formed according to some embodiments of the present disclosure; and

FIG. 12 is a schematic diagram of a display device according to some embodiments of the present disclosure.

### DETAILED DESCRIPTION

Hereinafter, only some exemplary embodiments are briefly described. As may be realized by those skilled in the art, the described embodiments may be modified in a variety of different ways without departing from the spirit or scope of the present disclosure. Therefore, the accompanying drawings and description shall be considered as exemplary but not limiting.

Transistors used in all the embodiments of the present disclosure may be thin film transistors or field-effect transistors or other devices with the same characteristics. The transistors used in the embodiments of the present disclosure are mainly switching transistors according to the functions in the circuit. Since a source and a drain of the switching transistor used here are symmetrical, the source and the drain are interchangeable. In the embodiments of the present disclosure, the source (source electrode) is referred to as a first electrode and the drain (drain electrode) is referred to as a second electrode. Alternatively, the drain is referred to as a first electrode and the source is referred to as a second electrode. According to the form in the drawings, it is specified that an intermediate terminal of the transistor is a gate (may also referred to as a gate electrode), a signal input terminal is the source, and a signal output terminal is the drain. In addition, the switching transistors used in the embodiments of the present disclosure may be P-type transistors or N-type transistors. The P-type transistor is turned on when the gate is at a low level and is turned off when the gate electrode is at a high level, and the N-type transistor is turned on when the gate electrode is at a high level and turned off when the gate electrode is at a low level. In addition, a plurality of signals in various embodiments of the present disclosure each correspond to a first potential and a second potential. The first potential and the second potential only represent that the signal has potentials with two different state quantities, but do not represent that the first potential or the second potential has a specific value in the whole text. The embodiments of the present disclosure are described by taking an example where the first potential is an effective potential.

Coupling may include a direct physical contact or an indirect connection between two ends (for example, a connection between two ends is established by a signal line). The manner in which two ends are coupled is not limited in the embodiments of the present disclosure.

For static electricity in a display product, an electrostatic discharge circuit may be used to discharge static electricity on the signal line. However, the electrostatic discharge circuit usually occupies a large space, which is disadvantageous to the achievement of the narrow bezel of the product. One end of the electrostatic discharge circuit is coupled to the signal line requiring electrostatic protection, and the other end of the electrostatic discharge circuit is coupled to an electrostatic protection line (e.g., a common electrode line or a short-circuit ring, etc.). In order to discharge the static electricity generated on the signal line to the electrostatic protection line through the electrostatic discharge circuit, the electrostatic discharge circuit needs to have a self-turn-on function and can achieve “high-pass and low-cut”, that is, the electrostatic discharge circuit does not affect the stability of the normal working voltage on the signal line, and when thousands of volts of transient static electricity is generated on the signal line, the static electricity can be discharged through the electrostatic discharge circuit to the electrostatic protection line and dissipated.

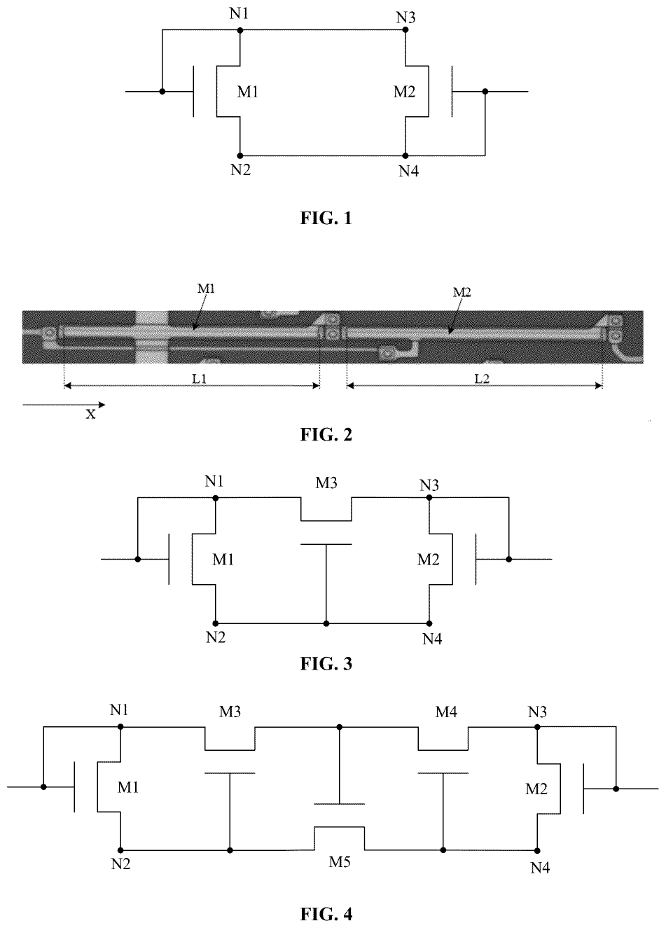

FIG. 1 is a schematic diagram of an electrostatic discharge circuit, and FIG. 2 is a schematic diagram of a partial structure of the electrostatic discharge circuit shown in FIG. 1. As shown in FIG. 1, the electrostatic discharge circuit includes a first transistor M1 and a second transistor M2. The first transistor M1 and the second transistor M2 are both thin film transistors (TFT). The gate and first electrode of the first transistor M1 are coupled to a first node N1, and the second electrode of the first transistor M1 is coupled to a second node N2. The gate and first electrode of the second transistor M2 are coupled to a third node N3, and the second electrode of the second transistor M2 is coupled to a fourth node N4. The first node N1 and the third node N3 are connected, and the second node N2 and the fourth node N4 are connected. The gate of the first transistor M1 is connected to a signal line on which the static electricity is to be discharged, and the gate of the second transistor M2 is connected to a common electrode line in a substrate.

When static electricity is generated on the signal line, the electrostatic voltage is usually greater than several hundreds of volts or even reaches several thousands of volts. Under the action of the electrostatic voltage, gates of the first transistor M1 and the second transistor M2 in the electrostatic discharge circuit are coupled. For example, the electrostatic voltage on the signal line drives the first transistor M1 to be turned on, and the static electricity flows through the first electrode of the first transistor M1 to the second electrode of the first transistor M1. Thus, the voltage of the second node N2 is less than the voltage of the first node N1. The second node N2 is connected to the common electrode line through the fourth node N4, and thus the static electricity at the first node N1 can pass through the first transistor M1 and is directly discharged to the common electrode line. The gate of the second transistor M2 is connected to the common electrode line, the gate voltage Vg of the second transistor M2 is 0, and only a micro current flows between the first electrode and second electrode of the second transistor M2. Therefore. the static electricity at the first node N1 is discharged to the common electrode line mainly through the first transistor M1. Since the voltage of the first node N1 is an electrostatic voltage and the voltage of the second node N2 is a common electrode voltage, the voltage difference VNIN2 between the first node N1 and the second node N2 is relatively large. Moreover, the gate-source voltage difference Vgs of the first transistor M1 is 0, the source-drain voltage difference Vds is relatively large, and the source-drain voltage difference Vds is approximately the electrostatic voltage. Therefore, the current per unit W/L in the working region of the first transistor M1 is relatively large. In order to discharge the static electricity, the current per unit W/L needs to be reduced. Here, W denotes a width of the channel of the TFT and L denotes a length of the channel of the TFT.

It is understandable that the normal working voltage of a signal line is usually tens of volts. e.g., about 10V. In order to prevent the electrostatic discharge circuit from affecting the normal working voltage of the signal line, the electrostatic discharge circuit needs to be in a high resistance state at the normal working voltage (low voltage) of the signal line. In some embodiments, in order that the electrostatic discharge circuit is in the high resistance state, as in the embodiment shown in FIG. 1, the length of the channel of the first transistor M1 is increased so as to increase the resistance of the channel, thereby reducing the current per unit W/L. That is, the length L of the channel of the first transistor M1 is increased to control the current flowable through the channel, thereby achieving the “high-pass and low-cut” of the electrostatic discharge circuit.

As shown in FIG. 1, the electrostatic discharge circuit is generally arranged as a symmetrical circuit, so the length L1 of the channel of the first transistor M1 and the length L2 of the channel of the second transistor M2 are relatively large.

As can be seen from FIG. 2, the length L1 of the channel of the first transistor M1 is relatively large, and the length L2 of the channel of the second transistor M2 is also relatively large. Since the lengths of the channels are relatively large, the electrostatic discharge circuit occupies a relatively large space, which is disadvantageous to the achievement of the narrow bezel of the product.

Additionally, it is understandable that the TFTs in the electrostatic discharge circuit are generally formed at the same time as the TFTs in the pixel region and the driving region of the substrate. That is, the active layers of the TFTs in the electrostatic discharge circuit are made of the same material as the active layers of the TFTs in the pixel region and the driving region. The lengths of the channels of the TFTs in the pixel region and the driving region are generally less than or equal to 5 micrometers (μm), whereas the lengths of the channel of the TFTs in the electrostatic discharge circuit are generally greater than 40 μm. In a bottom-gate TFT, if the length of the channel is greater than 40 μm, the formed TFT is insufficiently stable in terms of process, and metal easily remains on the channel surface of the TFT, and consequently the TFT loses its turn-off capability. This problem is especially serious when the length of the channel is greater than 50 μm.

Furthermore, the current of the TFT device increases with the increase of the mobility of the material of the active layer. In order to ensure the “high-pass and low-cut” of the electrostatic discharge circuit, the length of the channel of the TFT needs to continuously increase with the increase of the mobility. For example, the substrate adopts a metal-oxide double-gate TFT for display, and correspondingly the length of the channel of the TFT in the electrostatic discharge circuit is 150 μm to 400 μm. The TFT having such a length occupies a larger bezel space, and consequently the bezel of the product becomes larger, which is disadvantageous to the achievement of the narrow bezel of the product.

FIG. 3 is a schematic diagram of an electrostatic discharge circuit according to some embodiments of the present disclosure. As shown in FIG. 3, the electrostatic discharge circuit includes a first transistor M1, a second transistor M2, and a third transistor M3.

The gate and first electrode of the first transistor M1 are coupled to the first node N1, and the second electrode of the first transistor M1 is coupled to the second node N2. The first node N1 is coupled to a signal line on which the static electricity is to be discharged, that is, the gate of the first transistor M1 is coupled to the signal line.

The gate and first electrode of the second transistor M2 are coupled to the third node N3, and the second electrode of the second transistor M2 is coupled to the fourth node N4. As shown in FIG. 3, the fourth node N4 is coupled to the second node N2. The second node N2 is coupled to the electrostatic protection line. Optionally, the electrostatic protection line is a common electrode line, a short-circuit ring, or the like.

The gate of the third transistor M3 is coupled to the second node N2, the first electrode of the third transistor M3 is coupled to the first node N1, and the second electrode of the third transistor M3 is coupled to the third node N3.

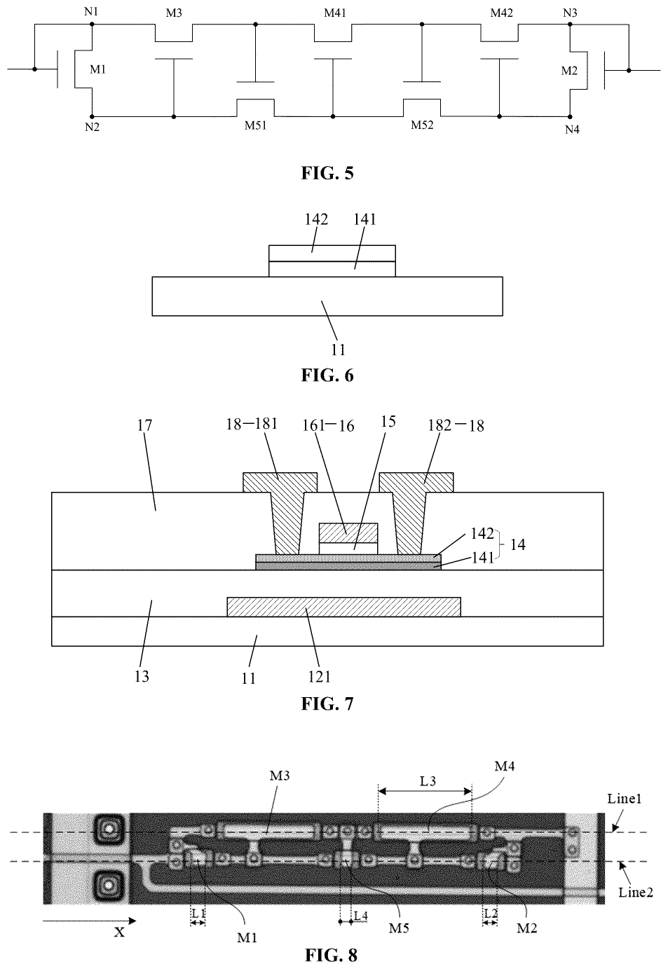

FIG. 4 is a schematic diagram of an electrostatic discharge circuit according to some embodiments of the present disclosure, and FIG. 5 is a schematic diagram of an electrostatic discharge circuit according to some embodiments of the present disclosure. As shown in FIG. 4 and FIG. 5, the electrostatic discharge circuit further includes N fourth transistors M4 and N fifth transistors M5, where N is a positive integer greater than or equal to 1.

The first electrodes and second electrodes of the N fourth transistors M4 are sequentially coupled in series, the first electrode of the first fourth transistor M4 is coupled to the second electrode of the third transistor M3, and the second electrode of the N-th fourth transistor M4 is coupled to the third node N3. That is, the second electrode of the third transistor M3 is coupled to the third node N3 through the N fourth transistors M4.

The first electrodes and second electrodes of the N fifth transistors M5 are sequentially coupled in series, the first electrode of the first fifth transistor M5 is coupled to the second node N2, and the second electrode of the N-th fifth transistor M5 is coupled to the fourth node N4. That is, the first electrodes and second electrodes of the N fifth transistors M5 are coupled in series between the second node N2 and the fourth node N4.

In the direction from the first transistor M1 to the second transistor M2, the gate of the i-th fourth transistor M4 is coupled to the second electrode of the i-th fifth transistor M5, the gate of the i-th fifth transistor M5 is coupled to the first electrode of the i-th fourth transistor M4, and the gate of the N-th fourth transistor M4 is coupled to the fourth node N4. Here, i is a positive integer not greater than N, that is, i is 1, 2, . . . . N.

It is understandable that the third transistor and the N fourth transistors M4 are arranged in the direction from the first transistor M1 to the second transistor M2, that is, the third transistor and the N fourth transistors M4 are sequentially arranged in the direction from the first transistor M1 to the second transistor M2: and the N fifth transistors M5 are sequentially arranged in the direction from the first transistor M1 to the second transistor M2.

In the embodiment shown in FIG. 3, the number of the third transistors M3 is 1, and the number of the fourth transistors M4 and the number of the fifth transistors M5 are both 0 (it may be understood that N equals to 0. As shown in FIG. 3. the first electrode of the third transistor M3 is coupled to the first node N1, the second electrode of the third transistor M3 is coupled to the third node N3, and the gate of the third transistor M3 is coupled to is coupled to the second node N2 or the fourth node N4.

In the embodiment shown in FIG. 4. N equals to 1, that is, the number of the fourth transistors M4 is 1 and the number of the fifth transistors M5 is 1. As shown in FIG. 4. the first electrode of the third transistor M3 is coupled to the first node N1, the second electrode of the third transistor M3 is coupled to the first electrode of the fourth transistor M4, and the second electrode of the fourth transistor M4 is coupled to the third node N3. The first electrode and second electrode of the fifth transistor M5 are coupled to the second node N2 and the fourth node N4, respectively, and the gate of the third transistor M3 is coupled to the first electrode of the fifth transistor M5, i.e., coupled to the second node N2. The gate of the fourth transistor M4 is coupled to the fourth node N4. i.e., coupled to the second electrode of the fifth transistor M5. The gate of the fifth transistor M5 is coupled to the second electrode of the third transistor M3 and the first electrode of the fourth transistor M4.

In the embodiment shown in FIG. 5. N equals to 2, that is, the number of the fourth transistors M4 is 2 and the number of the fifth transistors M5 is 2. As shown in FIG. 5. the first electrode of the third transistor M3 is coupled to the first node N1, the second electrode of the third transistor M3 is coupled to the first electrode of the first fourth transistor M41, the second electrode of the first fourth transistor M41 is coupled to the first electrode of the second fourth transistor M42, and the second electrode of the second fourth transistor M42 is coupled to the third node N3. The first electrode of the first fifth transistor M51 is coupled to the second node N2, the second electrode of the first fifth transistor M51 is coupled to the first electrode of the second fifth transistor M52, and the second electrode of the second fifth transistor M52 is coupled to the fourth node N4.

The gate of the third transistor M3 is coupled to the first electrode of the first fifth transistor M51, i.e., coupled to the second node N2. The gate of the first fourth transistor M41 is coupled to the first electrode of the second fifth transistor M52 and the second electrode of the first fifth transistor M51. The gate of the second fourth transistor M42 is coupled to the fourth node N4 and the second electrode of the second fifth transistor M52. The gate of the first fifth transistor M51 is coupled to the second electrode of the third transistor M3 and the first electrode of the first fourth transistor M41. The gate of the second fifth transistor M52 is coupled to the second electrode of the first fourth transistor M41 and the first electrode of the second fourth transistor M42.

FIG. 4 and FIG. 5 show the corresponding electrostatic discharge circuits when N is 1 and 2, respectively. In actual application. the value of N and the corresponding electrostatic discharge circuit can be determined based on the actual space occupied by the electrostatic discharge circuit.

Exemplarily: each transistor in the electrostatic discharge circuit is an N-type transistor, i.e., an NMOS transistor.

Taking the electrostatic discharge circuit shown in FIG. 3 as an example, the electrostatic discharge principle of the electrostatic discharge circuit in the technical solution of the present disclosure is as follows. Static electricity is generated on the signal line, the first transistor M1 is turned on under the action of the static electricity, and the electrostatic charge of the first node N1 flows through the first transistor M1 to the second node N2. The second node N2 controls the third transistor M3 to be turned on. The electrostatic charge of the first node N1 flows from the first node N1 to the third node N3. The third node N3 is connected to the electrostatic protection line, so the electrostatic charge of the third node N3 can be directly discharged. The gate of the second transistor M2 is connected to the electrostatic protection line. so the gate voltage Vg of the second transistor M2 is 0, the gate-source voltage difference Vgs of the second transistor M2 is 0, and only a micro current flows between the first electrode and second electrode of the second transistor M2. It can be seen that the static electricity of the first node N1 is discharged to the common electrode line mainly through the third transistor M3. Therefore, in FIG. 3, the first transistor M1 and the third transistor M3 cooperate to discharge the static electricity.

As shown in FIG. 3. the voltage of the second node N2 is less than the voltage of the first node N1. so the voltage has been lowered down from the first node N1 to the second node N2. When the second node N2 turns on the third transistor M3, the source-drain voltage difference Vds of the third transistor M3 has already much less than the source-drain voltage difference Vds of the first transistor M1 as shown in FIG. 1. That is, when the first transistor M1 and the third transistor M3 cooperate to discharge the static electricity, the first transistor M1 and the third transistor M3 together play a role of reducing the source-drain voltage difference Vds. Thus, there is no need to set a larger channel length L to limit the electrostatic discharge current. Therefore, compared with FIG. 1, the electrostatic discharge circuit shown in FIG. 3 limits the electrostatic discharge current by lowering the Vds, and there is no need to set a larger channel length L to limit the electrostatic discharge current. It can be seen that, under the circumstance of achieving the same electrostatic discharge effect, the sum of the lengths of the channels of the various transistors in the embodiment shown in FIG. 3 of the present disclosure is less than the sum of the lengths of the channels of the various transistors in the embodiment shown in FIG. 1.

As can be seen from the above analysis, the first transistor M1, the third transistor M3. the fourth transistor M4, and the fifth transistor M5 in the electrostatic discharge circuit shown in FIG. 4 cooperate to discharge the static electricity. The first transistor M1 and the fifth transistor M5 both play a role of reducing the Vds, and thus the sum of the lengths of the channels of the various transistors in the embodiment shown in FIG. 4 is less than the sum of the lengths of the channels of the various transistors in the embodiment shown in FIG. 1.

In addition, it has been verified by testing that while achieving the same electrostatic discharge effect as the electrostatic discharge circuit shown in FIG. 1, the area occupied by the electrostatic discharge circuit provided in the embodiments of the present disclosure is greatly reduced, which is advantageous to the achievement of a narrow bezel.

In the electrostatic discharge circuit provided in the embodiments of the present disclosure, the third transistor M3, the N fourth transistors M4, the N fifth transistors M5, and the first transistor M1 cooperate to discharge the static electricity, which reduces the Vds of the transistors, thereby limiting a portion of the electrostatic discharge current. Therefore, compared with the electrostatic discharge circuit in the embodiment shown in FIG. 1, the sum of the lengths of the channels of the various transistors in the electrostatic discharge circuit provided in the embodiments of the present disclosure can be greatly reduced, and the area occupied by the electrostatic discharge circuit can be greatly reduced, which is advantageous to the achievement of a narrow bezel.

In an embodiment. the first transistor M1 and the second transistor M2 are symmetrically arranged, and the first transistor M1 and the second transistor M2 are of the same structure and have the same size. That is, the gates, the sources, the drains, and the active layers of the first transistor M1 and the second transistor M2 are of the same structure and have the same size. The third transistor M3 and the N fourth transistors M4 are of the same structure and have the same size. For example, the width of the channel of the third transistor M3 is equal to the widths of the channels of the N fourth transistors M4. and the length of the channel of the third transistor M3 is equal to the lengths of the channels of the N fourth transistors M4. The N fifth transistors M5 are of the same structure and have the same size.

In an embodiment, the width to length ratio of the channel of the third transistor M3 is less than the width to length ratio of the channel of the fifth transistor M5, and the length of the channel of the third transistor M3 is greater than the length of the channel of the fifth transistor M5.

As can be seen from the working principle of the electrostatic discharge circuit in the embodiments of the present disclosure, the electrostatic charge of the first node N1 is discharged mainly by flowing through the third transistor M3 and the N fourth transistors M4 to the third node N3, and the main devices for electrostatic discharge are the third transistor M3 and the N fourth transistors M4. By making the width-to-length ratio of the channel of the third transistor M3 and the width-to-length ratio of the channel of each of the fourth transistors M4 be smaller than the width-to-length ratio of the channel of the fifth transistor M5 and making the length of the channel of the third transistor M3 and the length of the channel of each of the fourth transistors M4 be greater than the length of the channel of the fifth transistor M5, it is advantageous for enhancing the “high-pass and low-cut” performance of the electrostatic discharge circuit, which can not only improve the electrostatic discharge capability but also increase the stability of the normal working signal of the signal line.

In an embodiment, the mobility of the material of the active layer 14 of each transistor in the electrostatic discharge circuit is greater than or equal to 10. Exemplarily, the mobility of the material of the active layer is greater than or equal to 20. It is understandable by those skilled in the art that, in the case that the mobility of the active layer 14 is greater than or equal to 10, in order to achieve the “high-pass and low-cut” performance of the electrostatic discharge circuit. the channel of the TFT in the electrostatic discharge circuit in the related art needs to be very long. e.g., 150 μm-400 μm. The electrostatic discharge circuit provided in the embodiments of the present disclosure is applied to the scenario where the mobility of the material of the active layer 14 is greater than or equal to 10, and the lengths of the channels of the third transistor M3 and the fourth transistor M4 are relatively small, which can reduce the area occupied by the electrostatic discharge circuit.

In a display substrate with a TFT device in which the mobility of the material of the active layer is greater than or equal to 20 and the threshold voltage Vth is negative, when the electrostatic discharge circuit in the embodiments of the present disclosure is used, the area occupied by the electrostatic discharge circuit can be effectively reduced, and a better electrostatic discharge effect can be achieved.

Optionally, in the electrostatic discharge circuit provided in the embodiments of the present disclosure, the material of the active layer 14 of each transistor includes a metal-oxide semiconductor material. For example, the material of the active layer 14 of each transistor includes at least one of indium gallium zinc tin oxide (IGZTO), indium gallium oxide (IGO). indium gallium zinc oxide (IGZO), or the like.

FIG. 6 is a schematic structural diagram of an active layer of a transistor according to some embodiments of the present disclosure. As shown in FIG. 6, the active layer 14 of the transistor includes a first active sub-layer 141 and a second active sub-layer 142 stacked on one side of a base 11, and the first active sub-layer 141 is closer to the base 11 than the second active sub-layer 142 is. The material of the first sub-layer layer 14 includes at least one of IGZTO or IGO; and the material of the second sub-layer layer 14 includes IGZO, and the atomic ratio of indium, gallium, and zinc in the material of the second active sub-layer 142 is 1:1:1.

It is understandable by those skilled in the art that the TFTs in the pixel region, the driving region and the electrostatic discharge circuit in the display substrate usually adopt active layers 14 made of the same material. In the case that the active layer 14 of the structure and material shown in FIG. 6 is adopted, the mobility of the active layer 14 can be further improved. thereby improving the display performance of the substrate. Moreover, in the case that the electrostatic discharge circuit provided in the embodiments of the present disclosure is adopted. the area occupied by the electrostatic discharge circuit will be increase.

As shown in FIG. 6. the thickness of the first active sub-layer 141 ranges from 10 nm to 20 nm, and the thickness of the second active sub-layer 142 ranges from 10 nm to 50 nm.

The TFTs in the electrostatic discharge circuit may be bottom-gate TFTs, top-gate TFTs, or dual-gate TFTs. The material of the active layer is not limited to metal oxides, and may also be low-temperature polycrystalline silicon (LTPS) or the like.

In an embodiment, the width to length ratio of the channel of the third transistor M3 is (2-5) μm/(40-80) μm. e.g., 3.5 μm/50 μm. In the case that the electrostatic discharge circuit in the related art shown in FIG. 1 is used, when the active layer is made of a metal-oxide semiconductor material, the length of the channel of the transistor ranges from 150 μm to 400 μm, e.g., 180 μm. The increase in the length of the channel increases the risk of the channel losing its turn-off capability and results in a larger area occupied by the electrostatic discharge circuit. In the electrostatic discharge circuit provided in the embodiments of the present disclosure, when the active layer of the TFT is made of a metal-oxide semiconductor material. the width to length ratio of the channel of the third transistor M3 may be set as (2-5) μm/(40-80) μm. Under this setting, not only the “high-pass and low-cut” of the electrostatic discharge circuit can be achieved, but also the length of the channel can be greatly reduced, thereby reducing the area occupied by the electrostatic discharge circuit, which is advantageous to the achievement of a narrow bezel.

In an embodiment. the width-to-length ratios of the channels of the first transistor M1 and the second transistor M2 are both (2-5) μm/(5-10) μm. e.g., 3.5 μm/8 μm.

The width-to-length ratio of the channel of the fourth transistor M4 is (2-5) μm/(5-10) μm. e.g., 3.5 μm/6.5 μm.

FIG. 7 is a schematic structural diagram of a third transistor in an electrostatic discharge circuit according to some embodiments of the present disclosure. In an embodiment, referring to FIG. 7. each transistor in the electrostatic discharge circuit includes an active layer 14, a gate 161, a first electrode 181, and a second electrode 182. An active material layer is disposed on a side of the base 11, and the active material layer includes the active layers 14 of the various transistors. A first insulating layer 15 is disposed on the side of the active material layer that faces away from the base 11. A first metal layer 16 is disposed on the side of the first insulating layer 15 that faces away from the base 11, and the first metal layer 16 includes the gates 161 of the various transistors. A second insulating layer 17 is disposed on the side of the first metal layer 16 that faces away from the base 11. A second metal layer 18 is disposed on the side of the second insulating layer 17 that faces away from the base 11, and the second metal layer 18 includes the first electrodes 181 and the second electrodes 182 of the various transistors. The first electrode 181 and the second electrode 182 are coupled to a first conductorized region and a second conductorized region of the corresponding active layer 14, respectively. The first conductorized region and the second conductorized region are located on opposite sides of the channel.

In the embodiments of the present disclosure, the transistors in the electrostatic discharge circuit may be top-gate thin film transistors, and an insulating layer (e.g., the first insulating layer 15 and the second insulating layer 17) is provided between the active layer 14 and the metal film layer above, which can prevent the metal material from retaining on the channel surface of the active layer 14, and avoid the failure of the channel turn-off capability due to the metal residue, thereby improving the performance of the transistor.

FIG. 8 is a schematic diagram of a partial structure of the electrostatic discharge circuit shown in FIG. 4. The various transistors are labeled in FIG. 8, the electrostatic discharge circuit is disposed on a side of the base 11, and the active layers 14 of various transistors are disposed in the same layer. The length directions of the channels of the various transistors are all along a first direction X. The first direction X is a horizontal direction in FIG. 8, and the first direction is a width direction of a bezel region of the substrate. The active layer 14 of the third transistor M3 and the active layers 14 of the N fourth transistors M4 are arranged in sequence along a first straight line, and the active layer 14 of the first transistor M1, the active layers 14 of the N fifth transistors M5 and the active layer 14 of the second transistor M2 are arranged in sequence along a second straight line. The first straight line and the second straight line are spaced apart from each other.

In an embodiment, as shown in FIG. 8, the first straight line and the second straight line both extend along the first direction X and are parallel to each other. Taking FIG. 4 and FIG. 8 as examples, the active layer 14 of the third transistor M3 and the active layers 14 of the fourth transistors M4 are arranged in sequence along the first straight line Line1, and the active layer 14 of the first transistor M1, the active layers 14 of the fifth transistors M5 and the active layer 14 of the second transistor M2 are arranged in sequence along the second straight line Line2. The first straight line Line1 and the second straight line 2 both extend along the first direction X and are parallel to each other.

Under this arrangement. since the length of the channel of the third transistor M3 and the length L3 of the channel of the fourth transistor M4 are large, the dimension of the electrostatic discharge circuit in the first direction X mainly depends on the sum of the lengths of the channels of the third transistor M3 and the N fourth transistors M4. In the electrostatic discharge circuit shown in FIG. 4, the length of the channel of the third transistor M3 and the length L3 of the channel of the fourth transistor M4 range from 40 μm to 80 μm. and the dimension of the electrostatic discharge circuit shown in FIG. 8 in the first direction X mainly depends on the sum of the lengths of the channels of the third transistor M3 and the fourth transistor M4. In the electrostatic discharge circuits shown in FIG. 1 and FIG. 2, the dimensions of the electrostatic discharge circuits in the first direction mainly depend on the sum L1+L2 of the lengths of the channels of the first transistor M1 and the second transistor M2.

In the electrostatic discharge circuit shown in FIG. 2, the width-to-length ratios of the channels of the first transistor M1 and the second transistor M2 are 3.5 μm/180 μm. and the lengths of the channels of the first transistor M1 and the second transistor M2 are about 180 μm. Obviously. 40 μm to 80 μm is much less than 180 μm. Therefore, the dimension in the first direction X occupied by the electrostatic discharge circuit in the embodiments of the present disclosure is much less than the dimensions in the first direction X occupied by the electrostatic discharge circuits in the related art shown in FIG. 1 and FIG. 2. and thus the space occupied by the electrostatic discharge circuit in the embodiments of the present disclosure is greatly reduced. which is advantageous to the design of a narrow bezel.

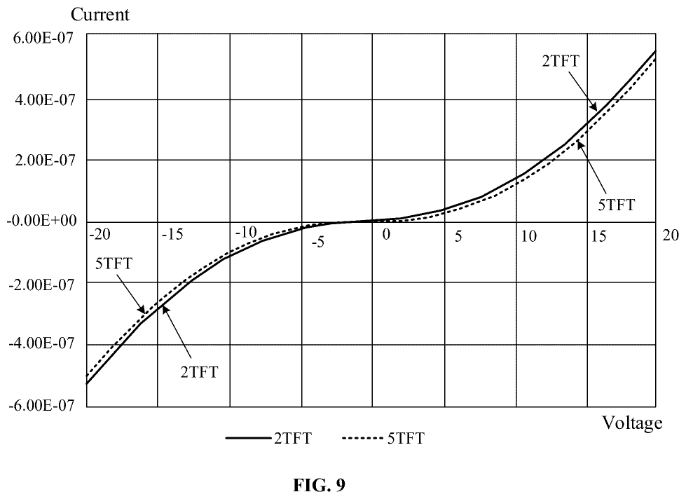

FIG. 9 is a schematic diagram showing a comparison of a current-voltage (I-V) characteristic curve of an electrostatic discharge circuit where N=1 in the embodiments of the present disclosure and an I-V characteristic curve of the electrostatic discharge circuit shown in FIG. 1. The curve corresponding to 2TFT is the I-V characteristic curve of the electrostatic discharge circuit in the related art shown in FIG. 1, and the curve corresponding to 5TFT is the I-V characteristic curve of the electrostatic discharge circuit where N=1 in the present disclosure. As can be seen from FIG. 9. the I-V characteristic curve of the electrostatic discharge circuit where N=1 in the present disclosure is the same as the I-V characteristic curve of the electrostatic discharge circuit in the related art shown in FIG. 1. Therefore, the effect of the electrostatic discharge circuit in the related art shown in FIG. 1 can be achieved by using the electrostatic discharge circuit in the present disclosure is used, and the electrostatic discharge circuit in the present disclosure occupies a smaller area.

It is understandable that the schematic diagrams of the electrostatic discharge circuits where N=1 and N=2 are shown above, and it is understandable that N is not limited to 1 and 2, and the specific value of N can be set flexibly according to the actual requirements for the product.

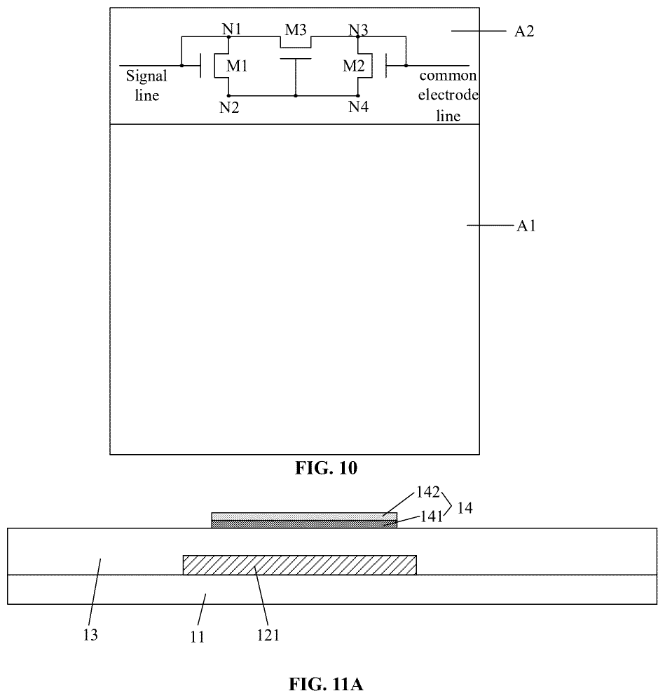

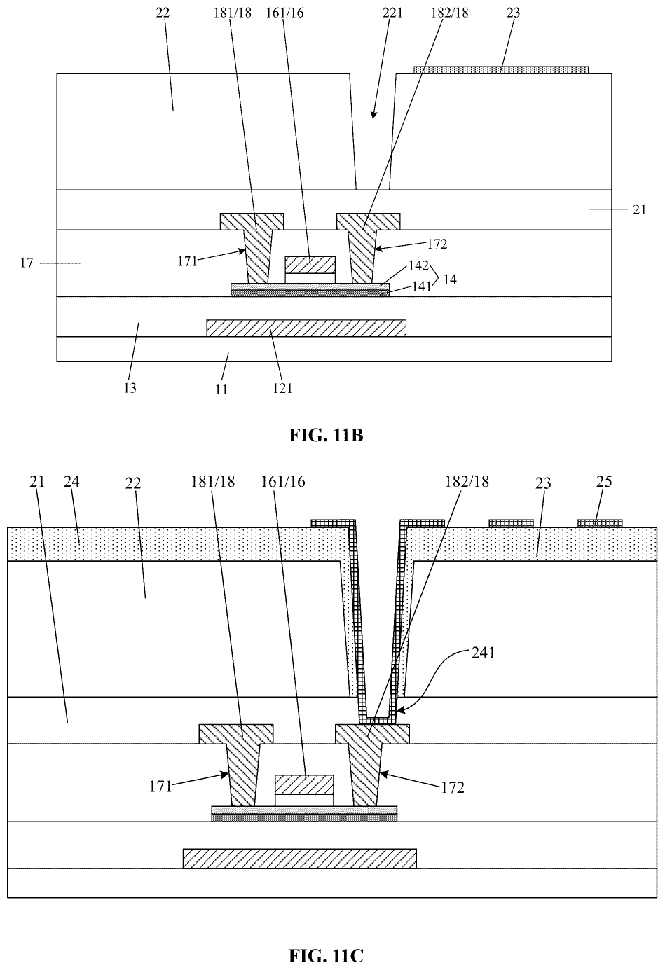

The embodiments of the present disclosure further provide a display substrate. As shown in FIG. 10, the display substrate has a display region A1 and a non-display region A2. The display substrate includes the electrostatic discharge circuit provided in any one of the embodiments of the present disclosure, and the electrostatic discharge circuit is disposed in the non-display region A2. When the electrostatic discharge circuit in the embodiments of the present disclosure is adopted, the electrostatic discharge circuit can discharge the static electricity for the signal lines of the display substrate, and the area of the bezel region occupied by the electrostatic discharge circuit can be reduced, which is advantageous to the design of a narrow bezel.

As shown in FIG. 10, the display substrate further includes a signal line and a common electrode line, the gate of the first transistor M1 in the electrostatic discharge circuit is coupled to the signal line, and the gate of the second transistor M2 is coupled to the common electrode line. Therefore, when static electricity is generated on the signal line, the electrostatic charge can be discharged to the common electrode line through the electrostatic discharge circuit, thereby achieving the discharge of the static electricity. Exemplarily, the signal line includes a data line.

The process for preparing the display substrate adopting the electrostatic discharge circuit provided in the embodiments of the present disclosure is described below in conjunction with the accompanying drawings. In the following embodiments, the process for preparing the various transistors in the display region and the bezel region and the structures of the transistors are described by taking the structure of the transistor in the display region as an example. It is understandable that, in respect of “patterning” herein, when the patterning material is an inorganic material or metal, “patterning” includes processes such as photoresist coating, mask exposure, development, etching, and photoresist strippin; and when the patterning material is an organic material, “patterning” includes processes such as mask exposure and development. Evaporation, deposition, coating and the like mentioned herein are all mature preparation processes in the related art.

A third metal layer is formed on a side of the base 11, e.g., glass, and the third metal layer includes a light-shielding portion 121, as shown in FIG. 11A, which is a sectional schematic diagram of a display substrate after an active layer is formed according to some embodiments of the present disclosure.

A buffer layer 13 is formed on the side of the third metal layer that faces away from the base 11, as shown in FIG. 11A. The thickness of the buffer layer 13 ranges from 200 nm to 500 nm.

An active material layer is deposited on the side of the buffer layer 13 that faces away from the base 11, and the material of the active material layer includes a metal-oxide semiconductor with a high mobility. The active material layer includes a first active material sub-layer and a second active material sub-layer, and the first active material sub-layer is closer to the base 11 than the second active material sub-layer is. The active material layer is annealed and then patterned to form the active layers 14 of the various thin film transistors. The active layer 14 includes a first active sub-layer 141 and a second active sub-layer 142 which are stacked. The material of the first active sub-layer 141 includes at least one of IGZTO or IGO: and the material of the second sub-layer layer 14 includes IGZO, and the atomic ratio of indium, gallium, and zinc in the material of the second active sub-layer 142 is 1:1:1. The thickness of the first active sub-layer 141 ranges from 10 nm to 20 nm, and the thickness of the second active sub-layer 142 ranges from 10 nm to 50 nm.

A first insulating layer 15 and a first metal film are sequentially deposited on the side of the active material layer that faces away from the base 11, and the first metal film is patterned to form a first metal layer 16. The first metal layer 16 includes the gates 161 of the various transistors and a gate line disposed in the display region. The first insulating layer 15 is etched using the first metal layer 16 as a mask to remove the first insulating layer 15 outside the first metal layer 16, as shown in FIG. 7. The thickness of the first insulating layer 15 ranges from 10 nm to 30 nm.

The active layer 14 is conductorized, and the conductorization process may be performed using plasma gases of helium (He), argon (Ar), hydrogen (H₂), ammonia (NH₃) and the like, or plasma gases of mixed gases. After the active layer 14 is conductorized, the active layer 14 includes a channel and a first conductorized region and a second conductorized region which are disposed on two sides of the channel.

A second insulating layer 17 is deposited on the side of the first metal layer 16 that faces away from the base 11, and the second insulating layer 17 is patterned to form a first via and a second via. The thickness of the second insulating layer 17 ranges from 300 nm to 600 nm.

A second metal layer 18 is formed on the side of the second insulating layer 17 that faces away from the base 11, and the second metal layer 18 includes the first electrodes 181 and the second electrodes 182 of the various transistors. The first electrode 181 is connected to the first conductorized region of the corresponding active layer 14 through the first via, and the second electrode 182 is connected to the second conductorized region of the corresponding active layer 14 through the second via, as shown in FIG. 7.

A first passivation layer 21 is deposited on the side of the second metal layer 18 that faces away from the base 11, and the side of the first passivation layer 21 that faces away from the base 11 is coated with a planarization layer 22. The planarization layer 22 is patterned to form a third via 221 located in the display region, as shown in FIG. 11B, which is a sectional schematic diagram of a display substrate after a common electrode is formed according to some embodiments of the present disclosure.

A common electrode 23 is formed on the side of the planarization layer 22 that faces away from the base 11. As shown in FIG. 11B, the common electrode 23 is disposed in the display region.

A second passivation layer 24 is deposited on the side of the common electrode 23 that faces away from the base 11, and the second passivation layer 24 and the first passivation layer 21 are patterned to form a fourth via 241 located in the display region. The fourth via 241 exposes a portion of the surface of the second electrode 182, as shown in FIG. 11C, which is a sectional schematic diagram of a display substrate after a pixel electrode is formed according to some embodiments of the present disclosure.

A pixel electrode 25 disposed in the display region is formed on the side of the second passivation layer 24 that faces away from the base 11, and the pixel electrode 25 is connected to the second electrode 182 through the fourth via 241, as shown in FIG. 11C. Exemplarily, the pixel electrode 25 is a strip electrode, the common electrode 23 is a planar electrode, and a driving electric field is generated between the pixel electrode 25 and the common electrode 23.

In example embodiments, the first insulating layer, the second insulating layer, the passivation layer, and the buffer layer are made of any one or more of silicon oxide (SiOx), silicon nitride (SiNx), or silicon oxynitride (SiON), and may be a single layer, multiple layers, or a composite layer. The buffer (Buffer) layer is used for improving the substrate's resistance to water and oxygen, the first insulating layer is referred to as a gate insulating (GI) layer, and the second insulating layer is referred to as an interlayer dielectric (ILD) layer. The metal layer structures such as the gates, the sources, the drains, and the metal traces are made of a metal material. For example, the metal material may be selected from a group including any one or more of argentum (Ag), copper (Cu), aluminum (Al), titanium (Ti), and molybdenum (Mo), or may be an alloy of the above metals such as an aluminum-neodymium alloy (AlNd) and a molybdenum-niobium alloy (MoNb). Moreover, the metal layer structure may be a single layer structure or a multilayer composite structure such as Ti/Al/Ti, etc. The common electrode and the pixel electrode are made of a transparent conductive material such as indium tin oxide (ITO) and indium zinc oxide (IZO). The active layer is made of an amorphous indium gallium zinc oxide (a-IGZO) material, zinc nitrogen oxide (ZnON), indium zinc tin oxide (IZTO), amorphous silicon (a-Si), polycrystalline silicon (p-Si), sexithiophene, polythiophene, or the like, that is, the present disclosure is applicable to transistors manufactured by an oxide technology, a silicon technology, and an organic substance technology.

The display substrate is a substrate used for display, such as an array substrate in a liquid crystal display, an organic light-emitting diode (OLED) display substrate, and a quantum dot light-emitting diode (QLED) display substrate.

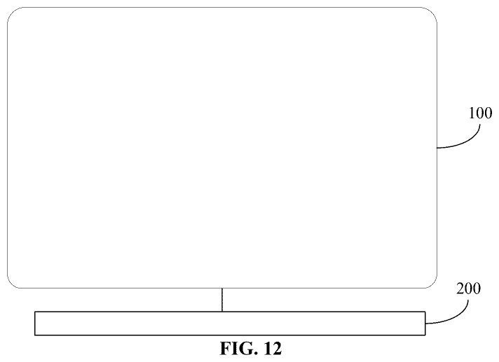

The embodiments of the present disclosure further provide a display device, and the display device includes the electrostatic discharge circuit provided in any one of the embodiments of the present disclosure, a signal line, and an electrostatic protection line. Alternatively, as shown in FIG. 12, the display device includes the display substrate 100 provided in any one of the embodiments of the present disclosure and a power supply assembly 200. The power supply assembly 200 is connected to the display substrate 100 and is configured to supply power to the display substrate 100.

The display device may be any product or component having a display function, such as a mobile phone, a tablet computer, a television, a display, a laptop computer, a digital photo frame, and a navigator.

It should be noted that the terms “center”, “longitudinal”, “lateral”, “length”, “width”, “thickness”. “on”, “under”. “front”, “back”, “left”, “right”, “vertical”, “horizontal”, “top”. “bottom”, “inside”, “outer”, “clockwise”, “counterclockwise”, “axial”, “radial”, “circumferential”, and the like indicating orientations or positional relationships in the description of the present specification are based on the orientations or positional relationships shown in the accompanying drawings and are merely used for the convenience of describing the present disclosure and simplifying the description, but not intended to indicate or imply that the indicated device or element must be in particular orientation or be constructed and operated in a particular orientation. Therefore, these terms should not be construed as a limitation of the present disclosure.

Furthermore, the terms “first” and “second” are used for descriptive purposes only and are cannot be construed as indicating or implying any relative importance or implicitly specifying the number of indicated technical features. Therefore, the features defined by the terms “first” and “second” may expressly or implicitly include one or more such features. In the description of the present disclosure. “a plurality of” means two or more, unless otherwise expressly and specifically limited.

In the present disclosure, unless otherwise expressly specified and defined, the terms “mount”, “connect with”, “connect to”, “fix”, and the like shall be broadly construed. For example, a connection may be a fixed connection, a detachable connection, or an integrated connection. It it may be a mechanical connection, an electrical connection, or a communication connection, it may be a direct connection or an indirect connection through an intermediate medium, and it may be an internal connection of two elements or an interactive relationship between two elements. Those of ordinary skill in the art can understand the specific meaning of the above terms in the present disclosure according to the specific circumstances.

In the present disclosure, unless otherwise expressly specified and defined, the first feature being “on” or “under” the second feature includes a direct contact between the first and second features or an indirect contact between the first and second features through another feature between them. Furthermore, the first feature being “on”, “above” or “over” the second feature includes that the first feature is right above or sidely above the second feature or merely represents that the horizontal height of the first feature is greater than the horizontal height of the second feature. The first feature being “under”, “below” or “beneath” the second feature includes that the first feature is right below or sidely below the second feature or merely represents that the horizontal height of the first feature is less than the horizontal height of the second feature.

The disclosure above provides many different embodiments or examples to implement different structures of the present disclosure. For simplifying the present disclosure, parts and arrangements of specific examples are described above. Certainly, they are merely examples but not intended to limit the present disclosure. In addition, the numbers and/or reference letters may be repeated in different examples of the present disclosure, and such a repetition is for the purposes of simplicity and clarity and is not in itself indicative of the relationship between the various implementations and/or arrangements discussed.

Described above are specific embodiments of the present disclosure, and the protection scope of the present disclosure is not limited thereto. Within the technical scope of the present disclosure, any variations or substitutions readily derived by those skilled in the art shall be included in the protection scope of the present disclosure. Therefore, the protection scope of the present disclosure is determined by the protection scope of the claims.

1. An electrostatic discharge circuit, comprising:
a first transistor, wherein a gate and a first electrode of the first transistor are both coupled to a first node, the first node being coupled to a signal line, and a second electrode of the first transistor is coupled to a second node;
a second transistor, wherein a gate and a first electrode of the second transistor are both coupled to a third node, the third node being coupled to an electrostatic protection line, and a second electrode of the second transistor is coupled to a fourth node, the fourth node being coupled to the second node; and
a third transistor, wherein a gate of the third transistor is coupled to the second node, a first electrode of the third transistor is coupled to the first node, and a second electrode of the third transistor is coupled to the third node.

2. The electrostatic discharge circuit according to claim 1, further comprising:
N fourth transistors, wherein first electrodes and second electrodes of the N fourth transistors are sequentially coupled in series, a first electrode of a first fourth transistor is coupled to the second electrode of the third transistor, and a second electrode of an N-th fourth transistor is coupled to the third node; and
N fifth transistors, wherein first electrodes and second electrodes of the N fifth transistors are sequentially coupled in series, a first electrode of a first fifth transistor is coupled to the second node, and a second electrode of an N-th fifth transistor is coupled to the fourth node;
wherein in a direction from the first transistor to the second transistor, a gate of an i-th fourth transistor is coupled to a second electrode of an i-th fifth transistor, and a gate of the i-th fifth transistor is coupled to a first electrode of the i-th fourth transistor, wherein N is a positive integer greater than or equal to 1, and i is a positive integer not greater than N.

3. The electrostatic discharge circuit according to claim 2, wherein N is 1 or 2.

4. The electrostatic discharge circuit according to claim 2, wherein a width of a channel of the fourth transistor is equal to a width of a channel of the third transistor, and a length of the channel of the fourth transistor is equal to a length of the channel of the third transistor.

5. The electrostatic discharge circuit according to claim 4, wherein a width-to-length ratio of the channel of the third transistor is less than a width-to-length ratio of a channel of the fifth transistor, and the length of the channel of the third transistor is greater than a length of the channel of the fifth transistor.

6. The electrostatic discharge circuit according to claim 5, wherein the width-to-length ratio of the channel of the third transistor is (2-5) μm/(40-80) μm.

7. The electrostatic discharge circuit according to claim 5, wherein a width-to-length ratio of a channel of the first transistor and a width-to-length ratio of a channel of the second transistor are both (2-5) μm/(5-10) μm.

8. The electrostatic discharge circuit according to claim 5, wherein the width-to-length ratio of the channel of the fifth transistor is (2-5) μm (5-10) μm.

9. The electrostatic discharge circuit according to claim 2, wherein the electrostatic discharge circuit is disposed on a side of a base, and active layers of various transistors in the electrostatic discharge circuit are disposed in a same layer;
wherein an active layer of the third transistor and active layers of the N fourth transistors are sequentially arranged along a first straight line, and an active layer of the first transistor, active layers of the N fifth transistors, and an active layer of the second transistor are sequentially arranged along a second straight line, wherein the first straight line and the second straight line are spaced apart from each other.

10. The electrostatic discharge circuit according to claim 9, wherein length directions of channels of the various transistors in the electrostatic discharge circuit are all a first direction, and the first straight line and the second straight line both extend along the first direction and are parallel to each other.

11. The electrostatic discharge circuit according to claim 1, wherein mobilities of materials of active layers of various transistors in the electrostatic discharge circuit are greater than or equal to 10.

12. The electrostatic discharge circuit according to claim 10, wherein materials of active layers of various transistors in the electrostatic discharge circuit comprise a metal-oxide semiconductor material.

13. The electrostatic discharge circuit according to claim 12, wherein the active layers of the various transistors in the electrostatic discharge circuit each comprise a first active sub-layer and a second active sub-layer which are stacked on the side of the base, the first active sub-layer being closer to the base than the second active sub-layer is;
wherein a material of the first active sub-layer comprises indium gallium zinc tin oxide, indium gallium oxide, or any combination thereof, and a material of the second active sub-layer comprises indium gallium zinc oxide.

14. The electrostatic discharge circuit according to claim 13, wherein an atomic ratio of indium, gallium, and zinc in the material of the second active sub-layer is 1:1:1.

15. The electrostatic discharge circuit according to claim 13, wherein a thickness of the first active sub-layer ranges from 10 nm to 20 nm, and a thickness of the second active sub-layer ranges from 10 nm to 50 nm.

16. The electrostatic discharge circuit according to claim 1, comprising:
an active material layer disposed on a side of a base, wherein the active material layer comprises active layers of various transistors;
a first insulating layer disposed on a side of the active material layer that faces away from the base;
a first metal layer disposed on a side of the first insulating layer that faces away from the base, wherein the first metal layer comprises gates of the various transistors;
a second insulating layer disposed on a side of the first metal layer that faces away from the base; and
a second metal layer disposed on a side of the second insulating layer that faces away from the base, wherein the second metal layer comprises first electrodes and second electrodes of the various transistors, and the first electrode and the second electrode are coupled to a first conductorized region and a second conductorized region of a corresponding active layer, respectively.

17. The electrostatic discharge circuit according to claim 1, wherein various transistors in the electrostatic discharge circuit are all N-type transistors.

18. A display substrate, having a display region and a non-display region, the display substrate comprising an electrostatic discharge circuit, wherein the electrostatic discharge circuit is disposed in the non-display region, and comprises:
a first transistor, wherein a gate and a first electrode of the first transistor are both coupled to a first node, the first node being coupled to a signal line, and a second electrode of the first transistor is coupled to a second node;
a second transistor, wherein a gate and a first electrode of the second transistor are both coupled to a third node, the third node being coupled to an electrostatic protection line, and a second electrode of the second transistor is coupled to a fourth node, the fourth node being coupled to the second node; and
a third transistor, wherein a gate of the third transistor is coupled to the second node, a first electrode of the third transistor is coupled to the first node, and a second electrode of the third transistor is coupled to the third node.

19. The display substrate according to claim 18, further comprising: the signal line and a common electrode line; wherein the gate of the first transistor in the electrostatic discharge circuit is coupled to the signal line, and the gate of the second transistor in the electrostatic discharge circuit is coupled to the common electrode line.

20. A display device, wherein the display device comprises: a signal line, an electrostatic protection line, and an electrostatic discharge circuit, wherein the electrostatic discharge circuit comprises: a first transistor, a second transistor, and a third transistor; wherein a gate and a first electrode of the first transistor are both coupled to a first node, the first node being coupled to a signal line, and a second electrode of the first transistor is coupled to a second node; a gate and a first electrode of the second transistor are both coupled to a third node, the third node being coupled to an electrostatic protection line, and a second electrode of the second transistor is coupled to a fourth node, the fourth node being coupled to the second node; and a gate of the third transistor is coupled to the second node, a first electrode of the third transistor is coupled to the first node, and a second electrode of the third transistor is coupled to the third node; or
the display device comprising: a power supply assembly, and the display substrate, wherein the display substrate has a display region and a non-display region and comprises an electrostatic discharge circuit, wherein the electrostatic discharge circuit is disposed in the non-display region, and comprises: a first transistor, a second transistor, and a third transistor; wherein a gate and a first electrode of the first transistor are both coupled to a first node, the first node being coupled to a signal line, and a second electrode of the first transistor is coupled to a second node; a gate and a first electrode of the second transistor are both coupled to a third node, the third node being coupled to an electrostatic protection line, and a second electrode of the second transistor is coupled to a fourth node, the fourth node being coupled to the second node; and a gate of the third transistor is coupled to the second node, a first electrode of the third transistor is coupled to the first node, and a second electrode of the third transistor is coupled to the third node, and the power supply assembly is configured to supply power to the display substrate.
